(19) United States
(12) Patent Application Publication
(10) Pub. No.: US 2016/0148955 A1
(43) Pub. Date: May 26, 2016

(54) THIN FILM TRANSISTOR ARRAY PANEL AND METHOD FOR MANUFACTURING THE SAME

(71) Applicant: Samsung Display Co., Ltd., Yongin-city (KR)

(72) Inventors: Pil Soon Hong, Gwangmyeong-si (KR); Gwui-Hyun Park, Hwaseong-si (KR); Jin Ho Ju, Seoul (KR)

(21) Appl. No.: 14/701,276

(22) Filed: Apr. 30, 2015

(30) Foreign Application Priority Data
Nov. 26, 2014 (KR) 10-2014-0166441

(51) Int. Cl. H01L 27/12; H01L 29/423; H01L 29/786; H01L 21/285; H01L 21/311; H01L 21/027; H01L 21/3213; H01L 21/28; H01L 29/49; H01L 29/66

(52) U.S. Cl. CPC H01L 27/1222; H01L 29/4908; H01L 29/495; H01L 29/42372; H01L 29/42364; H01L 29/42384; H01L 29/78603; H01L 29/78669; H01L 29/78678; H01L 29/7869; H01L 29/66969; H01L 29/66765; H01L 21/31111; H01L 21/31144; H01L 21/0272; H01L 21/32133; H01L 21/32139; H01L 21/28079; H01L 21/28568; H01L 27/1288

(57) ABSTRACT

A thin film transistor array panel according to an exemplary embodiment of the present invention has a first gate insulting layer and a second gate insulating layer disposed on the first gate insulating layer. The gate electrode of the present invention is formed in an opening of the first gate insulating layer with the same height as that of the gate electrode. Therefore, the second gate insulating layer formed on the gate electrode and the first gate insulating layer renders a flat surface without a step. This may reduce or eliminate any defects caused by the step around gate electrodes, such as source electrode and/or drain electrode cracks.

### CROSS-REFERENCE TO RELATED APPLICATION

This application claims priority from and the benefit of Korean Patent Application No. 10-2014-0166441 filed on Nov. 26, 2014, which is hereby incorporated by reference for all purposes as if fully set forth herein.

### BACKGROUND

1. Field

Exemplary embodiments relate to a thin film transistor array panel and a method for manufacturing the same.

2. Discussion of the Background

In general, a thin film transistor (TFT) is used as a switching element for is independently driving each pixel in a flat panel display such as a liquid crystal display, an organic light emitting display, or the like. A thin film transistor array panel may include the thin film transistor, a pixel electrode connected to the thin film transistor, a gate line that transmits a gate signal to the thin film transistor, a data line that transmits a data signal to the thin film transistor, and the like.

The thin film transistor includes a gate electrode that is connected to the gate line so as to receive the gate signal, a semiconductor layer formed on the gate electrode, a source electrode that is formed on the semiconductor layer and connected to the data line so as to receive the data signal, and a drain electrode that is formed to be spaced apart from the source electrode and connected to the pixel electrode. In this case, the gate line, the gate electrode, the data line, the source electrode, the drain electrode, and the like may be formed by a metal wiring.

In order to improve resolution, a research that may increase pixel integration per unit area on the thin film transistor array panel has been carried out and in order to process an image signal at high speed, a research on using an oxide semiconductor having high electron mobility or a copper wiring having lower resistance has been conducted.

In this case, in order to implement a high-resolution display by using the low-resistance copper wiring , the copper wiring may be formed to be thick. In this case, once the copper wiring is formed to be thick, other metal wirings including the source and drain electrodes which may be formed on the copper wiring may be disconnected due to a step that may be caused by the thickness of the copper wiring. This may cause a crack of the other wirings.

The above information disclosed in this Background section is only for enhancement of understanding of the background of the invention and therefore it may contain information that does not form the prior art that is already known in this country to a person of ordinary skill in the art.

### SUMMARY

Exemplary embodiments provide a thin film transistor array panel and a method for manufacturing the same that prevents other wirings formed on a low-resistance wiring from being disconnected.

Additional aspects will be set forth in the detailed description which follows, and, in part, will be apparent from the disclosure, or may be learned by practice of the inventive concept.

According to exemplary embodiments, a thin film transistor array panel comprises: a first gate insulting layer disposed on a substrate and including a gate opening that exposes a portion of the substrate; a gate electrode disposed in the gate opening; a second gate insulating layer disposed on the first gate insulating layer and the gate electrode; a semiconductor layer formed on the second gate insulating layer; a source electrode and a drain electrode that are disposed to be spaced apart from each other on the semiconductor layer; a passivation layer disposed on the second gate insulating layer, the source electrode, and the drain electrode; and a pixel electrode disposed on the passivation layer and connected to the drain electrode, wherein the gate electrode has a side that is inversely tapered.

The gate electrode may be made of copper.

The gate electrode may have a thickness of 1 μm or more.

The second gate insulating layer may have an upper surface that is flat.

The first gate insulating layer and the gate electrode may have the same thickness.

The first gate insulating layer and the second gate insulating layer may be made of the same material.

The gate electrode may have an upper surface that is positioned over or below an upper surface of the first gate insulating layer.

According to exemplary embodiments, a method for manufacturing a thin film transistor array panel comprises: forming a first gate insulating layer on a substrate; forming a gate opening that exposes a portion of the substrate in the first gate insulating layer; forming a gate electrode in the gate opening; forming a second gate insulating layer on the first gate insulating layer and the gate electrode; forming a semiconductor layer on the second gate insulating layer; forming a source electrode and a drain electrode that are spaced apart from each other on the semiconductor layer; forming a passivation layer on the second gate insulating layer, the source electrode, and the drain electrode; and forming a pixel electrode connected to the drain electrode on the passivation layer.

The forming of the gate opening may include sequentially forming a first resist layer and a second resist layer on the first gate insulating layer; forming a first resist opening in the first resist layer and a second resist opening in the second resist layer by exposing and developing the first resist layer and the second resist layer; and etching the first gate insulating layer using the first resist layer and the second resist layer as a mask.

The first resist opening may expose a portion of the first gate insulating layer and may be formed below the second resist opening.

The first resist opening may be wider than the second resist opening.

The first resist layer may not have photosensitivity and may have solubility for a developer, and the second resist layer may have photosensitivity and may have solubility for the developer.

The forming of the gate electrode may include forming a gate metal layer on the second resist layer and the substrate that is exposed by the gate opening; and removing the first resist layer, the second resist layer, and the gate metal layer formed on the second resist layer by a lift-off process.

The forming of the gate opening may include forming a third resist layer including a third resist opening on the first gate insulating layer; and etching the first gate insulating layer using the third resist layer as a mask.

The forming of the gate electrode may include removing the third resist layer; forming a gate metal layer on the first gate insulating layer and the substrate that is exposed by the gate opening; forming a fourth resist layer on the gate metal layer, wherein the fourth resist layer is formed in a portion corresponding to the gate opening; etching the gate metal layer using the fourth resist pattern as a mask; and removing the fourth resist layer and the gate metal layer formed on the gate opening.

According to a conventional method, a copper wiring is formed first on a substrate and then an insulating layer is formed on the copper wiring protruding on the substrate. This causes a step depending on the thickness of the copper wiring and the step causes a crack in other wirings formed on the insulating layer.

However, according to an embodiment of the present invention, the first gate insulating layer having the same thickness as that of the gate electrode is formed on the substrate and then the gate opening in which the gate electrode is disposed is formed in the first gate insulating layer. Even though the gate electrode is formed to be thick, therefore, an upper surface of both the gate electrode and the first gate insulating layer may be flat without a step because the thickness of the first gate insulating layer may be the same as that of the gate electrode. Consequently, it is possible to prevent the other wirings including the source and drain electrodes from being disconnected due to the step because the upper surfaces of the gate electrode and the first gate insulating layer on which the other wirings may be formed is flat.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a layout view of a thin film transistor array panel according to an exemplary embodiment of the present invention.

FIG. 2 is a cross-sectional view taken along the line II-II for the thin film transistor array panel of FIG. 1.

FIGS. 3 through 8 are views schematically showing a method for manufacturing a thin film transistor array panel according to an exemplary embodiment of the present invention.

FIGS. 9 through 11 are views schematically showing a method for manufacturing a thin film transistor array panel according to another exemplary embodiment of the present invention.

FIG. 12 is a cross-sectional view schematically showing a thin film transistor array panel according to another exemplary embodiment of the present invention.

FIG. 13 is a cross-sectional view schematically showing a thin film transistor array panel according to still another exemplary embodiment of the present invention.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

In addition, throughout the specification, when an element is referred to as “a plane shape”, it means when the element is viewed from a top thereof, and when an element is referred to as “a cross-section shape”, it means when a vertically cut cross-section of the element is viewed from a side thereof.

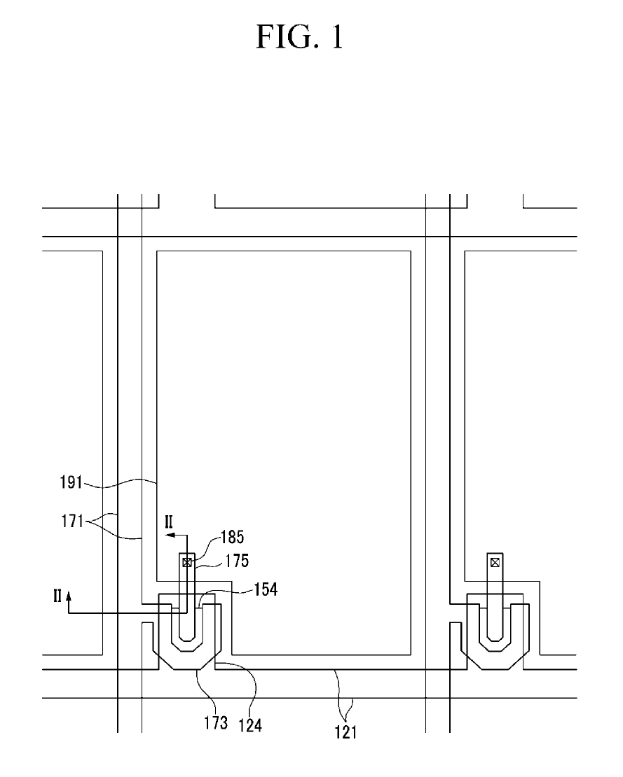

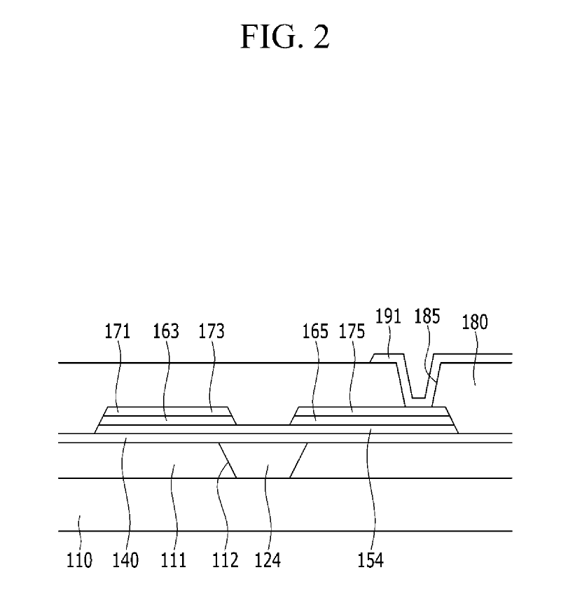

FIG. 1 is a layout view of a thin film transistor array panel according to an exemplary embodiment of the present invention. FIG. 2 is a cross-sectional view taken along the line II-II for the thin film transistor array panel of FIG. 1.

Referring to FIGS. 1 and 2, a thin film transistor array panel according to the exemplary embodiment includes a plurality of thin film structures such as a first gate insulating layer 111, a plurality of gate lines 121, a plurality of semiconductor layers 154, a plurality of data lines 171, a plurality of drain electrodes 175, a plurality of pixel electrodes 191, and the like.

The thin film structures will be described in more detail. The first gate insulating layer 111 and the plurality of gate lines 121 are disposed on a substrate 110 that is made of an insulating material such as glass, plastic, or the like.

The first gate insulating layer 111 may be made of an inorganic insulating material such as silicon nitride (SiNx), silicon oxide (SiOx), or the like. A gate opening 112 that exposes a portion of the substrate 110 may be formed in the first gate insulating layer 111. Referring to FIG. 2, the gate opening 112 has a side that is inversely tapered toward an upper surface of the substrate 110.

The gate line 121 transfers a gate signal and is mainly extended in a horizontal direction. Each gate line 121 includes a plurality of gate electrodes 124 that protrude in an upward direction on a plane shape. The gate electrode 124 is disposed in the gate opening 112. The gate electrode 124 has a side that is inversely tapered toward the upper surface of the substrate 110. The gate electrode 124 may be made of a metal material having low resistance such as copper (Cu), or the like, and may be formed to have a thickness of 1 μm or more so as to decrease resistance of a wiring. The first gate insulating layer 111 may have the same thickness as that of the gate electrode 124.

In addition, the first gate insulating layer 111 further includes the gate opening in which the gate line 121 is disposed.

A second gate insulating layer 140 is disposed on the first gate insulating layer 111 and the gate electrode 124. The second gate insulating layer 140 may be made of an inorganic insulating material such as silicon nitride, silicon oxide, or the like. The first gate insulating layer 111 and the second gate insulating layer 140 may be made of the same material.

A plurality of semiconductor layers 154 are disposed on the second gate insulating layer 140. The semiconductor layer 154 may be made of an amorphous silicon semiconductor, a poly crystal silicon semiconductor, an oxide semiconductor, or the like. If the semiconductor layer 154 is made of the oxide semiconductor, it may use materials such as indium gallium zinc oxide (IGZO), zinc tin oxide (ZTO), indium tin oxide (IZO), and the like. The semiconductor layer 154 overlaps the gate electrode 124.

A plurality of data lines 171 and a plurality of drain electrodes 175 are disposed on the semiconductor layer 154. The data line 171 transfers a data signal and is mainly extended in a vertical direction so as to intersect with the gate line 121 (FIG. 1). Each data line 171 includes a plurality of source electrodes 173 which are extended to the gate electrode 124. The drain electrode 175 is separated from the data line 171 and faces the source electrode 173 while having the gate electrode 124 at the center therebetween. The data line 171 and drain electrode 175 may be made of a metal material having low resistance.

Ohmic contact layers 163 and 165 are disposed between the semiconductor layer 154, and the data line 171 and the drain electrode 175. The ohmic contact layers 163 and 165 may decrease contact resistance between the semiconductor layer 154, and the data line 171 and the drain electrode 175.

Meanwhile, the exemplary embodiment describes the structure in which the plurality of data lines 171 and the plurality of drain electrodes 175 are disposed on the semiconductor layer 154, but the present invention is not limited thereto. For example, only portions of the source electrode 173 and the drain electrode 175 may be disposed on the semiconductor layer 154 and other portions of the source electrode 173 and the drain electrode 175, and the data lines 171 may be disposed on the second gate insulating layer 140. In this case, the ohmic contact layers 163 and 165 may be disposed only between the semiconductor layer 154 and the portions of the source electrode 173 and the drain electrode 175 disposed on the semiconductor layer 154. A thin film transistor (TFT) includes the gate electrode 124, the source electrode 173, the drain electrode 175 and the semiconductor layer 154, and a channel of the thin film transistor is formed in the semiconductor layer 154 between the source electrode 173 and the drain electrode 175.

A passivation layer 180 is disposed on the second gate insulating layer 140, the data line 171, and the drain electrode 175. The passivation layer 180 may be made of an inorganic insulating material such as silicon nitride (SiNx), silicon oxide (SiOx), or the like. In addition, the passivation layer 180 is not limited thereto, and may also have a dual layer structure including an inorganic layer made of an inorganic insulating material and an organic layer made of an organic insulating material such as polymethylmethacrylate (PMMA), polyvinylpyrrolidone (PVP), polyvinylacetate (PVA), parylene, etc. However, the organic insulating material is not limited thereto. A contact hole 185 that exposes the drain electrode 175 may be formed in the passivation layer 180.

The pixel electrode 191 that is connected to the drain electrode 175 through the contact hole 185 is disposed on the passivation layer 180. The pixel electrode 191 may be made of a transparent metal material such as an indium tin oxide (ITO), an indium zinc oxide (IZO), or the like.

Since the first gate insulating layer 111 and the gate electrode 124 have the same thickness and the gate electrode 124 is disposed in the gate opening 112, an upper surface of the second gate insulating layer 140 and the gate electrode 124 may become flat. Consequently, the step between the gate electrode and the gate insulating layer when applying the conventional method may be avoided. Thus, the data line 171 and the drain electrode 175 may be formed without defects such as a crack, or the like that are usually caused by the step.

Hereinafter, a method for manufacturing a thin film transistor array panel according to an exemplary embodiment of the present invention will be described with reference to FIGS. 1, 2, and 3 through 8.

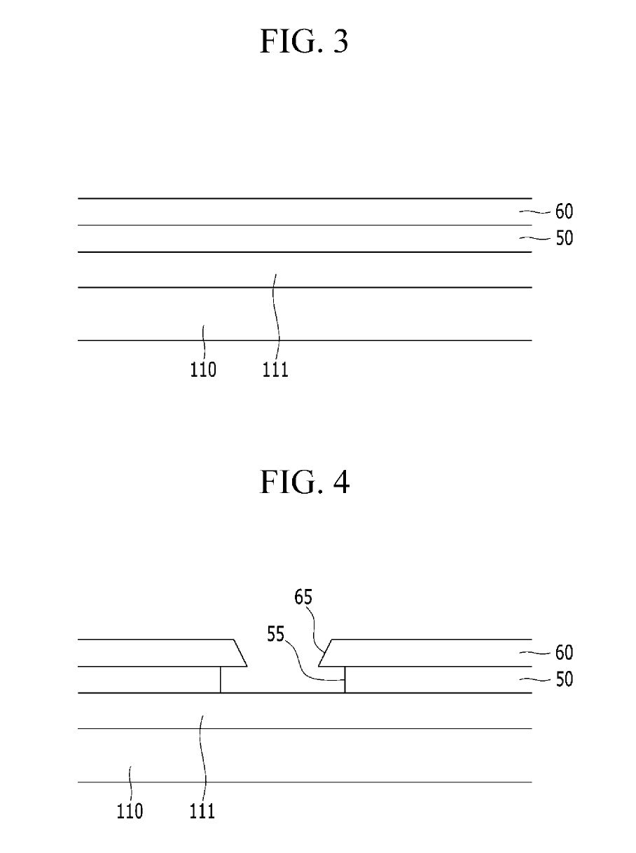

FIGS. 3 through 8 are views schematically showing a method for manufacturing a thin film transistor array panel according to an exemplary embodiment of the present invention.

Referring to FIG. 3, after the first gate insulating layer 111 is formed on the substrate 110, a first resist layer 50 and a second resist layer 60 are sequentially formed on the first gate insulating layer 111.

The first resist layer 50 does not have photosensitivity and has only solubility for a developer. The first resist layer 50 may include a resin and a solvent. The resin has solubility for a developer, particularly, an alkali developer, and may include a monomer such as a hydroxyl group, a carboxylic group, an alcoholic hydroxyl group, a phenolic hydroxyl group, or the like.

The second resist layer 60 has photosensitivity and solubility for a developer. The second resist layer 60 may include a resin, a photoactive compound, and a solvent. The second resist layer 60 is coated on the first resist layer 50. When coating the second resist layer 60, a solvent material such as 2-heptanone or cyclohexanon that does not solve the first resist layer 50 is used e not to make the second resist layer 60 mixed with the first resist layer 50.

Referring to FIG. 4, by exposing and developing the first and second resist layers 50 and 60, a second resist opening 65 is formed in the second resist layer 60 and a first resist opening 55 is formed in the first resist layer 50. The first resist opening 55 is formed below the second resist opening 65.

If the second resist layer 60 is exposed and then developed, the second resist opening 65 is formed. In this case, the developer contacts the first resist layer 50 that is exposed through the second resist opening 65. Then, the exposed first resist layer 50 portion is developed, which results in the first resist opening 55.

Since the second resist layer 60 except for the second resist opening 65 has photosensitivity, it is exposed but not developed by the developer. However, since the first resist layer 50 does not have photosensitivity and has only solubility for a developer, it is not influenced by the exposure and developed up to a portion that is wider than a width of the second resist opening 65 by the developer introduced through the second resist opening 65.

Therefore, the first resist opening 55 is wider than the second resist opening 65. Therefore, the first resist opening 55 and the second resist opening 65 have under cut formed therein (FIG. 4).

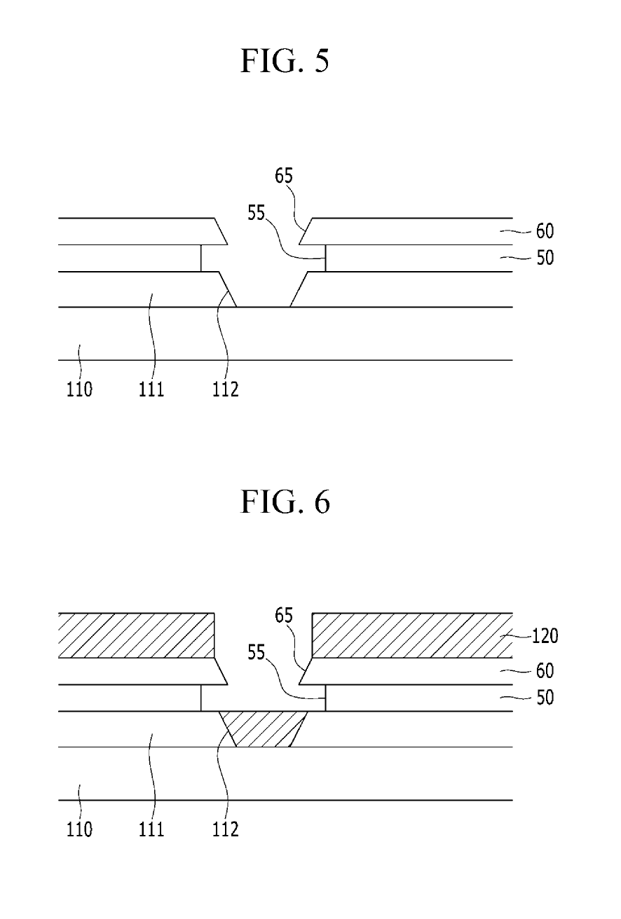

Referring to FIG. 5, a gate opening 112 that exposes a portion of the substrate 110 is formed by etching the first gate insulating layer 111 using the second resist layer 60 and the first resist layer 50 as a mask.

Referring to FIG. 6, a gate metal layer 120 may be deposited on an entire surface of the substrate 110. In this case, the gate metal layer 120 is formed on the second resist layer 60 and in the gate opening 112.

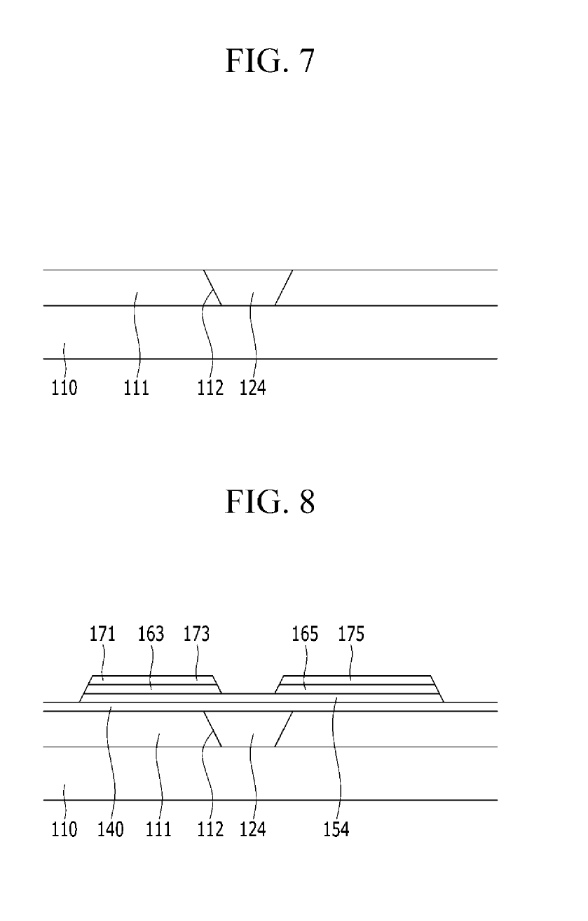

Referring to FIG. 7, the gate electrode 124 is formed in the gate opening 112 by removing the first resist layer 50, the second resist layer 60 and the gate metal layer 120 on the layer 60 by a lift-off process. As a result, the first gate insulating layer 111 and the gate electrode 124 have the same thickness.

Once the first resist layer 50 is removed, the second resist layer 60 and the gate metal layer 120 formed on the second resist layer 60 are removed, such that the gate metal layer 120 formed in the gate opening 112 becomes the gate electrode 124. Meanwhile, other gate openings (not shown) are provided with the gate line 121.

Referring to FIG. 8, after the second gate insulating layer 140 is formed on the first gate insulating layer 111 and the gate electrode 124, the semiconductor layer 154, the ohmic contact layers 163 and 165, the data line 171 including the source electrode 173, and the drain electrode 175 are formed on the second gate insulating layer 140.

The semiconductor layer 154, the ohmic contact layers 163 and 165, the data line 171 including the source electrode 173, and the drain electrode 175 may be formed by using one mask. However, the present invention is not limited thereto. For example, after the semiconductor layer 154 is first formed by using a mask, the ohmic contact layers 163 and 165, the data line 171 including the source electrode 173, and the drain electrode 175 may also be formed by using another mask.

Referring to FIGS. 1 and 2, after the passivation layer 180 including the contact hole 185 that exposes the drain electrode 175 is formed on the second gate insulating layer 140, the data line 171, and the drain electrode 175, the pixel electrode 191 that is connected to the drain electrode 175 through the contact hole 185 is formed on the passivation layer 180.

Hereinafter, a method for manufacturing a thin film transistor array panel according to another exemplary embodiment of the present invention will be described with reference to FIGS. 1, 2, and 9 through 11.

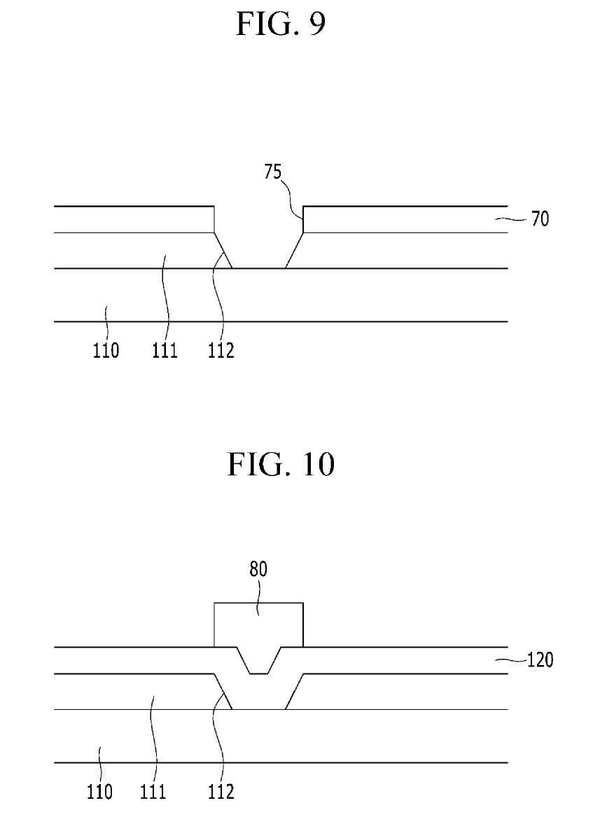

FIGS. 9 through 11 are views schematically showing a method for manufacturing a thin film transistor array panel according to another exemplary embodiment of the present invention.

Referring to FIG. 9, after the first gate insulating layer 111 is formed on the substrate 110, a third resist layer 70 including a third resist opening 75 is formed on the first gate insulating layer 111 and the gate opening 112 that exposes a portion of the substrate 110 is then formed by etching the first gate insulating layer 111 by using the third resist layer 70 as the mask. The third resist layer 70 has photosensitivity and solubility for a developer and the third resist opening 75 may be formed by the exposing and developing process like the second resist opening 65.

Referring to FIG. 10, after the third resist layer 70 is removed, the gate metal layer 120 is deposited on the first gate insulating layer 111 and the substrate 110 that is exposed by the gate opening 112 and then a fourth resist layer 80 is formed on the gate metal layer 120. The fourth resist layer 80 is formed in a portion corresponding to the gate opening 112.

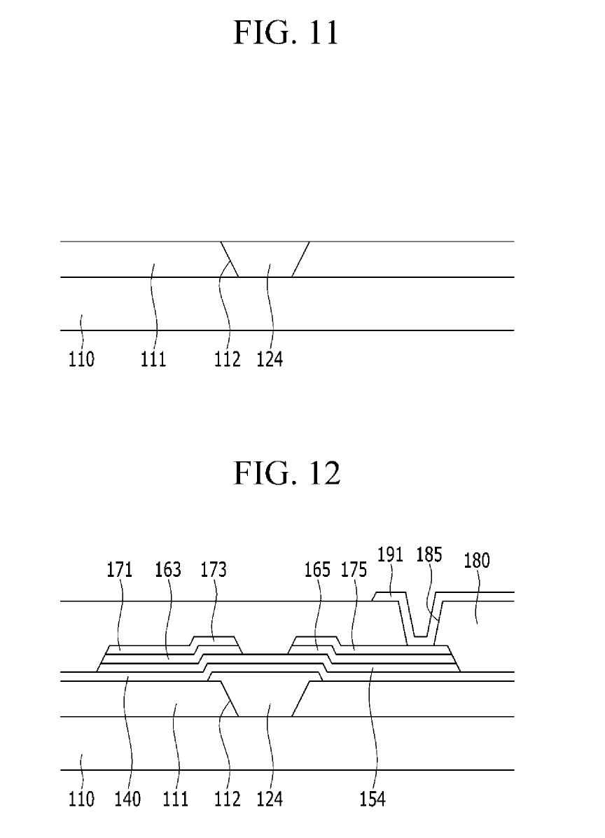

Referring to FIG. 11, after the gate metal layer 120 is etched using the fourth resist layer 80 as the mask, the gate electrode 124 is formed in the gate opening 112 by removing the fourth resist layer 80 and the gate metal layer 120 formed on the gate opening 112.

Meanwhile, other gate openings (not shown) are provided with the gate line 121.

Referring to FIGS. 1 and 2, after the second gate insulating layer 140 is formed on the first gate insulating layer 111 and the gate electrode 124, the semiconductor layer 154, the ohmic contact layers 163 and 165, the data line 171 including the source electrode 173, and the drain electrode 175 are formed on the second gate insulating layer 140.

After the passivation layer 180 including the contact hole 185 that exposes the drain electrode 175 is formed on the second gate insulating layer 140, the data line 171, and the drain electrode 175, the pixel electrode 191 that is connected to the drain electrode 175 through the contact hole 185 is formed on the passivation layer 180.

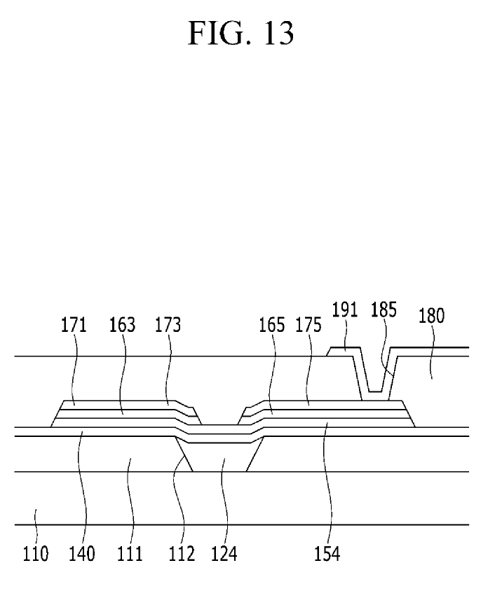

Hereinafter, a thin film transistor array panel according to another exemplary embodiment of the present invention will be described with reference to FIGS. 12 and 13.

FIG. 12 is a cross-sectional view schematically showing a thin film transistor array panel according to another exemplary embodiment of the present invention.

The thin film transistor array panel disclosed in FIG. 12 according to the another exemplary embodiment has only a different shape of the gate electrode as compared to the thin film transistor array panel according to FIG. 2, but has the same other structures. Therefore, a description of the same structures will be omitted.

Referring to FIG. 12, the gate electrode 124 is disposed in the gate opening 112 and an upper surface of the gate electrode 124 is positioned at a higher position than an upper surface of the first gate insulating layer 111. In this case, a portion of the gate electrode 124 is disposed on the first gate insulating layer 111. Thus, the data line 171, the source electrode 173, and the drain electrode 175 that are disposed on the second gate insulating layer 140 may form a slight step. However, since the slight step is an insignificant level as compared to the thickness of the gate electrode 124, the data line 171, the source electrode 173, and the drain electrode 175, it does not cause defect such as a crack, or the like.

FIG. 13 is a cross-sectional view schematically showing a thin film transistor array panel according to still another exemplary embodiment of the present invention.

The thin film transistor array panel disclosed in FIG. 13 according to the still another exemplary embodiment has only a different shape of the gate electrode as compared to the thin film transistor array panel according to FIG. 2, but has the same other structures. Therefore, a description of the same structures will be omitted.

Referring to FIG. 13, the gate electrode 124 is disposed in the gate opening 112 and an upper surface of the gate electrode 124 is positioned at a lower position than an upper surface of the first gate insulating layer 111. Therefore, the data line 171, the source electrode 173, and the drain electrode 175 that are disposed on the second gate insulating layer 140 may form a slight step. However, since the slight step is an insignificant level as compared to the thickness of the gate electrode 124, the data line 171, the source electrode 173, and the drain electrode 175, it does not cause defect such as a crack, or the like.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A thin film transistor array panel, comprising:
a first gate insulting layer disposed on a substrate and including a gate opening that exposes a portion of the substrate;
a gate electrode disposed in the gate opening;
a second gate insulating layer disposed on the first gate insulating layer and the gate electrode;
a semiconductor layer formed on the second gate insulating layer;
a source electrode and a drain electrode that are disposed to be spaced apart from each other on the semiconductor layer;
a passivation layer disposed on the second gate insulating layer, the source electrode, and the drain electrode; and
a pixel electrode disposed on the passivation layer and connected to the drain electrode,
wherein the gate electrode has a side that is inversely tapered.

2. The thin film transistor array panel of claim 1, wherein the gate electrode is made of copper.

3. The thin film transistor array panel of claim 2, wherein the gate electrode has a thickness of 1 μm or more.

4. The thin film transistor array panel of claim 3, wherein the second gate insulating layer has an upper surface that is flat.

5. The thin film transistor array panel of claim 1, wherein the first gate insulating layer and the gate electrode have the same thickness.

6. The thin film transistor array panel of claim 1, wherein the first gate insulating layer and the second gate insulating layer are made of the same material.

7. The thin film transistor array panel of claim 1, wherein the gate electrode has an upper surface that is positioned higher or lower than an upper surface of the first gate insulating layer.

8. A method for manufacturing a thin film transistor array panel, comprising:
forming a first gate insulating layer on a substrate;
forming a gate opening that exposes a portion of the substrate in the first gate insulating layer;
forming a gate electrode in the gate opening;
forming a second gate insulating layer on the first gate insulating layer and the gate electrode;
forming a semiconductor layer on the second gate insulating layer;
forming a source electrode and a drain electrode that are spaced apart from each other on the semiconductor layer;
forming a passivation layer on the second gate insulating layer, the source electrode, and the drain electrode; and
forming a pixel electrode connected to the drain electrode on the passivation layer.

9. The method of claim 8, wherein the step of forming a gate opening further comprises:
forming a first resist layer on the first gate insulating layer;
forming a second resist layer on the first resist layer;
exposing and developing the first resist layer and the second resist layer to form a first resist opening in the first resist layer and a second resist opening in the second resist layer; and
etching the first gate insulating layer using the first resist layer and the second resist layer as a mask.

10. The method of claim 9, wherein the first resist opening exposes a portion of the first gate insulating layer and is formed below the second resist opening.

11. The method of claim 10, wherein the first resist opening is wider than the second resist opening.

12. The method of claim 11, wherein the first resist layer has solubility for a developer and does not have photosensitivity, and
the second resist layer has both solubility for the developer and photosensitivity.

13. The method of claim 12, wherein the step of forming the gate electrode further comprises:
forming a gate metal layer on the second resist layer and the substrate that is exposed by the gate opening; and
removing the first resist layer, the second resist layer, and the gate metal layer formed on the second resist layer by a lift-off process.

14. The method of claim 8, wherein the step of forming a gate opening further comprises:
forming a third resist layer including a third resist opening on the first gate insulating layer; and
etching the first gate insulating layer using the third resist layer as a mask.

15. The method of claim 14, wherein the step of forming a gate electrode further comprises:
removing the third resist layer;
forming a gate metal layer on the first gate insulating layer and the substrate that is s exposed by the gate opening;
forming a fourth resist layer on the gate metal layer, wherein the fourth resist layer is formed in a portion corresponding to the gate opening;
etching the gate metal layer using the fourth resist layer as a mask; and
removing the fourth resist layer and the gate metal layer formed on the gate opening.

16. The method of claim 8, wherein the gate electrode is made of copper.

17. The method of claim 16, wherein the gate electrode has a thickness of 1 μm or more.

18. The method of claim 17, wherein the second gate insulating layer has an upper surface that is flat.

19. The method of claim 8, wherein the first gate insulating layer and the gate electrode have the same thickness.

20. The method of claim 8, wherein the first gate insulating layer and the second gate insulating layer are made of the same material.
